(19) United States
(12) Patent Application Publication
(10) Pub. No.: US 2011/0284364 A1
(43) Pub. Date: Nov. 24, 2011

(54) Aluminum Doped Zinc Oxide Sputtering Targets

(75) Inventors: Nikolaus MARGADANT, Maienfeld (CH); Guido HUYBERECHTS, Steenokkerzeel (BE); Paul LIPPENS, Waregem (BE); Anke BRÖNSTRUP, Weesen (CH)

(73) Assignee: UMICORE, Brussels (BE)

(21) Appl. No.: 13/108,195

(22) Filed: May 16, 2011

Related U.S. Application Data
(60) Provisional application No. 61/347,018, filed on May 21, 2010.

(51) Int. Cl. C23C 14/08; C04B 35/10; C04B 35/453; C23C 14/34

(52) U.S. Cl. 204/192.15; 204/298.13; 264/661

(57) ABSTRACT

A sputtering target precursor material comprises a homogeneous distribution of a ZnAl₂O₄ phase in a hexagonal ZnO phase, said ZnO phase further comprises less than 1 wt % of elemental Al in solid solution, expressed versus the total weight of said target material.

### RELATED APPLICATIONS

The present patent document claims the benefit of the filing date under 35 U.S.C. §119(e) of Provisional U.S. Patent Application No. 61/347,018, filed May 21, 2010, which is hereby incorporated by reference.

### TECHNICAL FIELD AND BACKGROUND

The invention relates to target materials for planar or rotary aluminium doped zinc oxide (Al:ZnO or AZO) sputtering targets. These are of interest for the deposition of transparent conductive films. Transparent conductive films may be used as front window contact in thin film photovoltaic products—such as TF-Si and CIGS modules—and as high index optical material in low-emissivity coating stacks for architectural glazing. As used herein, the term “target materials” refers to a sintered material that, after further machining, such as grinding, is transformed into a cylindrical target segment or a flat tile. At least one segment or tile is used to prepare a final sputtering target comprising these segments or tiles and a backing tube or plate.

It is recognized that DC sputtering at high power loads (for high deposition rate) is an economically appealing sputter deposition technology for large area coating. However, with high power loads, sputtering targets with inhomogeneous micro-structure (i.e., consisting of different phases with largely varying electrical conductivity) cause arcing and therefore instability during DC magnetron sputtering. In the case of aluminium doped zinc oxide, commercially available sputtering targets have an inhomogeneous distribution of Al into the ZnO phase or even free alumina (Al₂O₃) grains in the AZO ceramic. These inhomogeneities, in particular the loose domains with high zinc-aluminate content and free alumina residues, result in variations in conductivity on the target surface, or, in the case of free alumina, in dielectric centres that cause arcing during DC-sputtering. Arcing leads to reduced deposition rates and coating defects, which results in transparent conductive oxides (TCO's) with inferior electro-optical properties. Exemplary coating defects include, but are not limited to, pinholes, micro-structural defects and textural imperfections.

JP2000-178725 discloses a zinc oxide sintered body target, doped with a group III element, such as Ga, Al or B, and having a relative density of at least 97% of the TD (theoretical density), and a surface roughness Rmax in the sputtering face of less than 3.0 μm. The average particle size of the ZnO precursor powder is controlled to less than 1 μm, and sintering is executed at 1300 to 1500° C. in an oxygen atmosphere. The group III elements enter into a solid solution in ZnO.

In JP2007119805, a process is disclosed for manufacturing a sputtering target, comprising the steps of mixing water, an organic binder and an ammonia-neutralized acrylic acid/methacrylic acid copolymer dispersant, with a metal oxide powder containing at least 70 wt % of zinc oxide powder to obtain a slurry; spraying the resultant slurry and drying it to obtain a granulated powder; pressure-molding the resultant granulated powder to obtain a molding; sintering the resultant molding to obtain a sintered body; and a step of working the resultant sintered body to obtain a sputtering target.

JP2006200016 discloses a ZnO:Al target comprising a sintered compact which is formed from zinc, aluminum and oxygen, characterized in that the aluminum content is 2.3-3.5 wt % as oxide equivalent, and the mean crystal grain size of composite oxide ZnAlO₄ which is contained in said sintered compact is no more than 0.5 μm.

### SUMMARY

In a first aspect of the invention, a ceramic sputtering target material comprises a homogeneous distribution of a minority ZnAl₂O₄ phase in a hexagonal ZnO phase, said ZnO phase comprising less than 1 wt % of elemental Al in solid solution, expressed versus the total weight of said target material. Additionally, less than 1% of the total Al in the target material is present in Al₂O₃ domains in the target material.

The elemental Al is present either in the ZnAl₂O₄ phase or in the ZnO phase. The target material is composed of two phases: the hexagonal ZnO phase in which no or minor amounts of Al are in solid solution, and the cubic ZnAl₂O₄ phase in which the majority of the Al is contained and in which no or minor amounts of residual alumina can be found by XRD, as will be illustrated below. In an embodiment, the sputtering target precursor comprises between 250 ppm and 2 wt % of total Al. This composition promotes a high enough doping level in the target material to provide an electrical conductivity suitable for DC or pulsed DC sputtering. According to the state of the art in research, the herewith obtained thin film properties (e.g., transmittance and electric conductivity) are acceptable to outstanding.

In another embodiment, in the sputtering target material, the ZnO phase comprises less than 1 wt % of Al in solid solution, expressed versus the weight of the ZnO phase. Another embodiment covers a sputtering target precursor that is substantially free of Al₂O₃ domains larger than 0.5 μm. For purposes of this application, the phrase “substantially free” means free to a great or to a significant extent of Al₂O₃ domains larger than 0.5 μm (e.g., substantially free may include a sputtering target precursor that is 98%, 99%, 99.5%, 99.6%, 99.7%, 99.8%, or 99.9% free of Al₂O₃ domains larger than 0.5 μm). In yet another embodiment, the ZnAl₂O₄ phase consists of domains having an average equivalent diameter of less than 2 Ξm. Here, the average equivalent diameter (dₐᵥ) is calculated from the specific surface area, assuming spherical particles of equal size, according to the following formula:

$${d}_{av} = \frac{6}{ρ \times B E T} ,$$

in which ρ refers to the theoretical density of the powder and BET refers to the specific surface area (m²/g) as determined by the N₂ adsorption method of Brunauer-Emmett-Teller.

The invention can also provide a sputtering target material precursor in the form of a dried granulate having an apparent density of more than 1.1 g/cm³ and a tap density of more than 1.2 g/cm³, comprising ZnO and Al₂O₃ and up to 5 wt % of organic, temporary additives, such as binders or dispersants. In another embodiment, the sputtering target material precursor has a tap density between 1.3 and 1.5 g/cm³.

In a second aspect of the invention, a process for manufacturing a ceramic sputtering target material, comprises:
providing a ZnO powder having an average particle size less than 1 μm and an Al₂O₃ powder having an average particle size less than 1 μm,
dispersing said ZnO and Al₂O₃ powders homogeneously in an aqueous slurry,
spray-drying said slurry so as to obtain a dried granulate having an apparent density above 1.1 g/cm³, and a tap density above 1.2 g/cm³,
pressing said dried granulate to form a green body having a density above 50% of the theoretical density of the sputtering target, and
sintering said green body to obtain the ceramic sputtering target material at a temperature between 1200 and 1550° C.

In an embodiment of the process, in addition to ZnO and Al₂O₃ powders, there is provided up to 5 wt % of organic materials used as binder material, plasticizer and dispersant, and optionally a sintering aid, such as MgO.

In another embodiment, the Al₂O₃ powder has an average particle size that is smaller than the average particle size of said ZnO powder. In another embodiment, the ZnO powder has an average particle size between 150 nm and 1200 nm, and the Al₂O₃ powder has an average particle size between 50 and 800 nm. In yet another embodiment, the ZnO and Al₂O₃ powders each have a purity of at least 99.9%.

In a third aspect of the invention, the ceramic sputtering target material can be used for manufacturing a sputtering target having a density of at least 95% of the theoretical density. In an embodiment, the ceramic sputtering target material is used for manufacturing a hollow rotary sputtering target having an inner diameter of between 130 and 140 mm and an outer diameter between 155 and 185 mm. In another embodiment, the obtained sputtering target is used in a sputtering process for manufacturing an aluminum doped zinc oxide coating. The sputtering process can be a DC sputtering process with a power of more than 25 kW/m.

### BRIEF DESCRIPTION OF THE DRAWINGS

FIG. 1 is a schematic process flow diagram of an exemplary process for manufacturing an AZO rotary sputtering target.

FIG. 2 is a set of images of energy dispersive X-ray spectroscopy (EDX) mapping of target material prepared in Example 1.

FIG. 3 is a set of images of energy dispersive X-ray spectroscopy (EDX) mapping of target material prepared in Example 2.

FIG. 4 is a set of images of energy dispersive X-ray spectroscopy (EDX) mapping of target material prepared in Example 3.

### DETAILED DESCRIPTION

The invention relates to target materials having a homogeneous micro-structure and methods for producing said target materials. Target materials with a homogenous micro-structure increase process stability and efficiency during sputtering by promoting avoidance of arcing issues during sputtering. A homogenous microstructure can have an even distribution of Al over the entire micro-structure and/or can be free of isolated domains with high zinc aluminate (ZnAl₂O₄) content detached from the ZnO matrix (which have a negative effect on the electrical conductivity) and/or can be free of alumina grains significantly larger than the primary grain size of the ZnO-powder. As used herein, the phrase “free of alumina grains” can be understood to mean that no alumina is detectable with either XRD or in an optical microscope/SEM at magnification <2500×, on polished cross sections of the material.

The target material comprises two phases: a hexagonal ZnO phase in which no or minor amounts of Al are in solid solution, and a cubic ZnAl₂O₄ phase in which the majority of the Al is contained and in which no or minor amounts of residual alumina can be found by XRD. In an exemplary embodiment, no alumina particles with equivalent diameter of 0.5 μm or larger or isolated domains with a high Al-content—which are detached zinc aluminate particles larger than 2 μm—can be detected. The structural constituent aluminate formed during the chemical reaction between ZnO and Al₂O₃ forms only small coherent phase-areas with an average equivalent diameter of less than 2 μm, in order to avoid a detachment from the matrix due to volumetric changes accompanied by residual stresses.

In another exemplary embodiment, the order of magnitude of the zinc aluminate domains is in the same range or smaller than the ZnO primary particles, even if the grain size in the sintered material is significantly bigger. The transition of the Al-ions as dopant (into zinc aluminate) is much more likely if the Al₂O₃ powder grain has a maximum contact area with the material to be doped (i.e., each individual Al₂O₃-particle is surrounded by several ZnO-particles). In low-level doping, this maximum contact area arrangement allows for a high doping efficiency (i.e., an acceptable electrical conductivity). For purposes of this application, “low level doping” can be understood to mean less than 1 wt % total Al. In high-level doping, the non-conductive domains are very small and arcing is avoided. For purposes of this application, “high level doping” can be understood to mean more than 1 wt % total Al.

Advantageously, a more homogeneous microstructure of the sputtering target leads to the target having more homogeneous physical properties (e.g., electrical conductivity). The homogeneous properties lead to better, more stable sputtering behavior. For example, more stable sputtering behavior may include less arcing of rotatable and planar sputtering targets during DC and pulsed DC sputtering at high power loads (e.g., >25 kW/m DC power in case of rotary targets). Less arcing leads to higher deposition rates and thus higher productivity. Less arcing also leads to coatings, especially transparent conductive coatings, with optimized properties, such as less defects (nodules, particle formation) and pinholes.

The ceramic target material may be produced according to a powder metallurgical process. In the process, the starting components are powders with defined purity levels. The starting materials can be oxides (such as ZnO) and alumina, or compounds of alumina and zinc oxide (a zincate phase). In an exemplary embodiment, the precursor materials are oxidic powders ZnO and Al₂O₃ with a controlled purity level. For example, the main constituent ZnO has a purity of 3N or better. A precursor ZnO powder having a grain size with a d50 value <1 μm can be produced via a physical process (i.e., the so-called American or French processes). The Al₂O₃ precursor may also contain minor levels of a sintering aid (e.g., MgO). The primary grain size of Al₂O₃ precursor can be smaller than the particle size of ZnO.

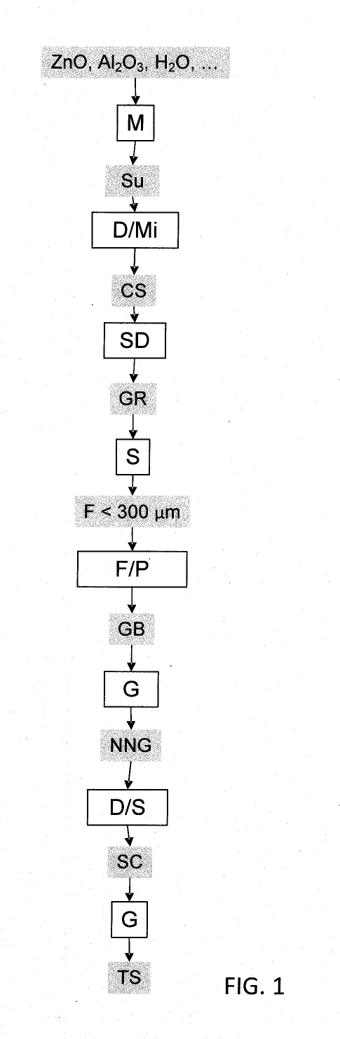

An exemplary process for manufacturing an AZO rotary sputtering target is shown in FIG. 1. As can be seen in FIG. 1, the exemplary process includes the following steps:
providing the precursors: ZnO, Al₂O₃, and binders, dispersants, water;
M: mixing of the precursors to obtain a suspension (Su);
D/Mi: dispersing and milling of the suspension to obtain a ceramic aqueous slurry (CS);
SD: spray-drying to obtain a granulate (GR);
S: sieving of the granulate to retain the fraction (F) below 300 μm;
F/P: filling and pressing the granulate by Cold Isostatic Pressing to obtain a green body (GB);
GM: green-machining the green body to obtain a near-net shaped GB (NNG);
D/S: debinding and (reactive) sintering the NNG to obtain sintered cylinder parts (i.e., the target material);
G: grinding of the sintered cylinders to obtain tube segments (TS) ready to be assembled into a sputtering target.

The precursor powders are processed as a watery dispersion or slurry by a sequence of dissolving and a combined milling and de-agglomeration process in a bead mill, followed by spray-drying for granulation. The granulation aids the stability of the mixtures and promotes homogeneity even for thick walled target material parts.

A number of process variable parameters are available for producing granules having various characteristics. The large number of variable parameters enables granules to be formed with exact pre-defined characteristics. For example, the size of the granules is affected by the materials being processed, the droplet size after atomization and the exhaust air temperature. Adjusting these parameters by known methods enables the skilled person to obtain given values for other characteristics, as well. Additional characteristics that can be adjusted using variable parameters include, for example, apparent and tap density, porosity, and granule hardness. For ZnO granules, most granulates are hollow.

The granulates can be shaped by cold compaction followed by green machining. Cold compaction may include axial or isostatic compaction. Hard agglomerates in between primary particles in the granulates can ultimately cause sintering defects such as voids in the product sputtering target. Thus, it is desirable to avoid hard agglomerates in between primary particles in the granulates because the applied pressures during compaction are often not sufficiently high to break the agglomerates.

It is desirable for the primary particles to have a high packing density. A high packing density of the primary particles results in the pore diameter in the green state being minimized. Accordingly, the particle size distribution is optimized to provide a high packing density of the primary particles. An optimized particle size distribution without hard agglomerates can be obtained and stabilized by an appropriate de-agglomeration, a dispersing and milling process in combination with organic additives and a subsequent granulation process. Additionally, a relatively broad bimodal distribution of the primary grains may also be advantageous to further increase packing density of the primary particles.

Modifying or altering characteristics of the granulates can affect downstream aspects of the process. For example, a high reproducibility in mould filling (e.g., same weight, low density fluctuations) and minimization, of compaction shrinkage can be achieved by using granulates having high flowability with a sufficiently high tap density. Further, in addition to granulate density, granulate size distribution, along with a high packing density, facilitates the densification step and causes less large inter-granular-pores after compaction and firing.

A green body having a green density of at least 50% TD after cold compaction can enable complete sintering because such a green body provides a pore network that can be eliminated during the sintering process without large residual pores. A sinter density of 95% TD or even higher can be obtained. In addition, the high green density reduces shrinkage of the component during firing and reduces the risk of distortion or warping, etc.

In an exemplary embodiment, the sputtering target precursor comprises as inactive and temporary materials up to 5 wt % of organic additives, which can be organic binders and dispersants. In practice, around 2 wt % can be sufficient to yield a good granulate stability, a good green strength and good plasticity while compacting. Levels higher than 5 wt % can be less desirable. The higher levels can result in sticky granules, a drop in green strength by viscous flow and a critical de-binding step during sintering due to gas evolution.

Machining of the green body allows for finishing the parts after sintering with a minimum of mechanical post treatment (e.g., grinding). Machining of the green body is easier to perform than grinding of a sintered compact and recycling of the non-fired material because high material removal rates are easily obtained with machining.

Pressureless sintering is a two-step process comprising a debinding step, wherein organic binders are burned off, and a final reaction sintering step. In an exemplary embodiment, after sintering, no residual Al₂O₃ is detectable in the sintered body with XRD. The reaction of Al₂O₃ with ZnO and transformation to zinc-aluminate is accompanied by a change in density. This reaction is restricted to a small zone. Detachment from the ZnO matrix within the zone can be avoided using the process described above. In fact, advantageously, the phase reaction occurs before sintering is completed. Thus, in case of a detachment or loss of contact points between the ZnO matrix and the zinc-aluminate phase during sintering, Al ions are not dissolved or diffused in the ZnO-matrix because of the elevated temperatures. Avoiding detachment and increasing the interfacial area enables a higher electrical conductivity and more homogeneous carrier distribution to be achieved. Such result is possible because more Al has gone into solid solution into the ZnO phase.

The sintering temperature should be kept high enough to reach maximum density and optimum conductivity. However, over-firing should be avoided. For AZO, sintering temperatures can be kept above 1200° C. and below 1550° C., for less than 10 hours at the soaking temperature. Over-firing may lead to undesirable characteristics in the sintered material. Such characteristics may include an uncontrolled microstructure in terms of grain growth and grain structure, an excessive sublimation of the zone near the surface, and/or vitrification resulting in sinter material with a different composition and conductivity than the regular AZO.

A target having a homogenous microstructure enables a high quality deposited thin film. For example, on the basis of sputtering evaluations, a link between the target inhomogeneity and the arcing behavior of the target during DC sputtering has been established. In addition, the target microstructure is verifiably reflected in the quality of the deposited thin film, especially on the concentration of the active dopants and their distribution.

The invention is further illustrated in the following examples:

### Example 1

The following testing was performed to evaluate the arc rate during DC sputtering using an exemplary embodiment of the target material of the present invention.

An AZO-2% Al₂O₃ rotary sputtering target, corresponding to a target material having 3.6 wt % ZnAl₂O₄, prepared according to the process described above, was used in a dynamic sputter deposition line with a vertical sputter magnetron. The rotary sputtering target had an inner diameter backing tube of 125 mm, an inner diameter of the AZO cylindrical segments of 135 mm and a 14 mm AZO wall thickness, for a length of 0.55 m. Coatings were deposited on clear glass (Schott B270) with power loads varying between 0 and 27.27 kW/m and at both 24° C. (RT) and 190° C. substrate temperature. The sputtering pressure was approximately 6.3. 10⁻³ mbar and various reactive gas mixtures were used, from pure argon (Ar) to 0.8% O₂ flow (in % of total gas flow). Coatings of approximately 1200 nm in thickness were deposited by passing the substrate 8 times in front of the sputter source at various speeds. An Advanced Energy Pinnacle™ DC power supply was used for testing. The target of the present invention yielded a micro-arc rate of less than 10 micro-arcs per second, even at 27.27 kW/m power load.

### Comparative Example 2

The same equipment used in Example 1 was used under exactly the same sputtering conditions with a commercially available sputtering target. The recorded micro-arc rate was between 30 and 40 micro-arcs/sec at power loads of 27.27 kW/m.

### Comparative Example 3

The same equipment used in Example 1 was used under exactly the same sputtering conditions with a second commercial sputtering target from a second supplier. The recorded micro-arc rate was just under 100 micro-arcs/sec at power loads of 27.27 kW/m.

The results of the sputtering experiments are summarized in Table 1.

TABLE 1
Total arc count in 10 min when ramping from 0 to the indicated power density using
Advanced Energy Pinnacle Plus ™ power supply in DC mode at a pressure P = 0.005 mbar
(working gas: Argon, target Ø 200 mm for cathode type ARQ131)

| Averaged Power | Sputter Material | | |
|---|---|---|---|
| Density | Commercial | Commercial | |
| [W/cm²] | target 1 | target 2 | Example 1 |
| (not pulsed!) | (Example 2) | (Example 3) | target |
| 0.8 | 30 | 311 | 26 |
| 1.6 | 413 | (3176) | 98 |
| 2.4 | 2094 | Abort | 203 |
| 3.2 | (2620) | Abort | 272 |

Different operating regimes can be distinguished:
in Bold letters: stable regime and power set point reached,
Between brackets: instable regime, set point only sometimes reached,
“Abort”: instable regime & cycle aborted through pinnacle control.

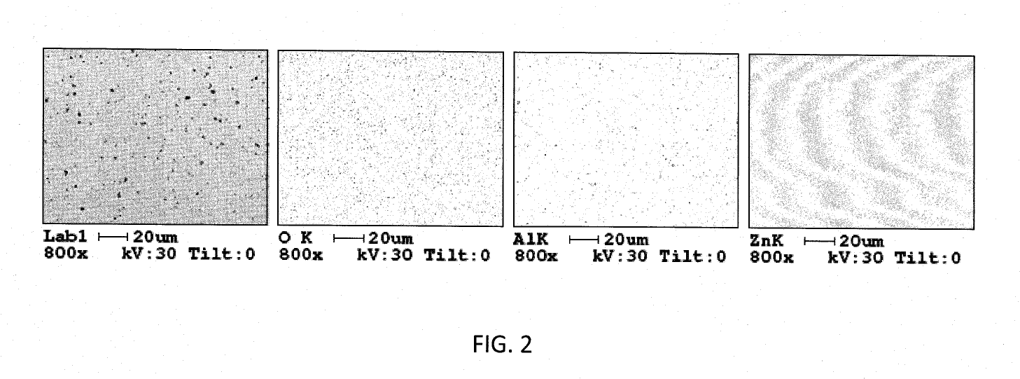

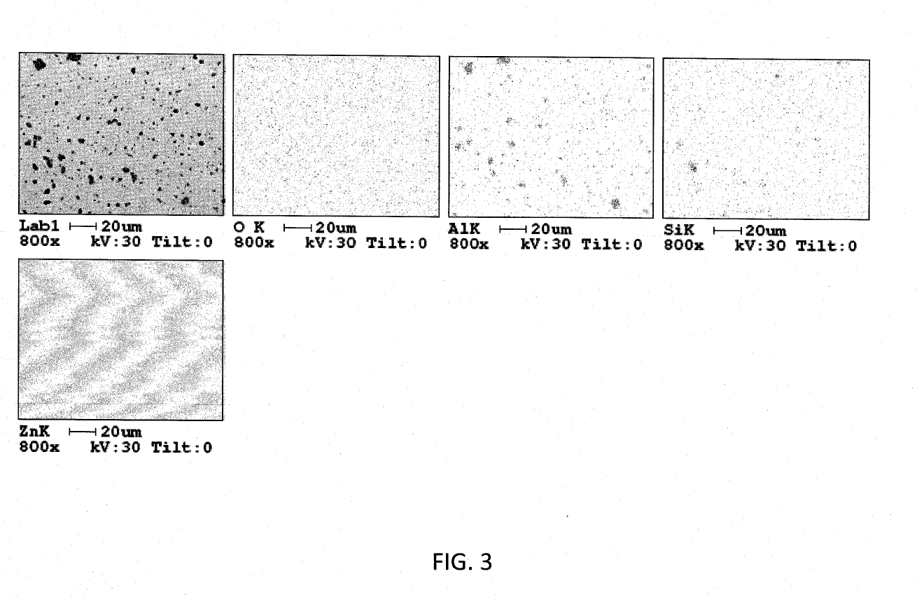

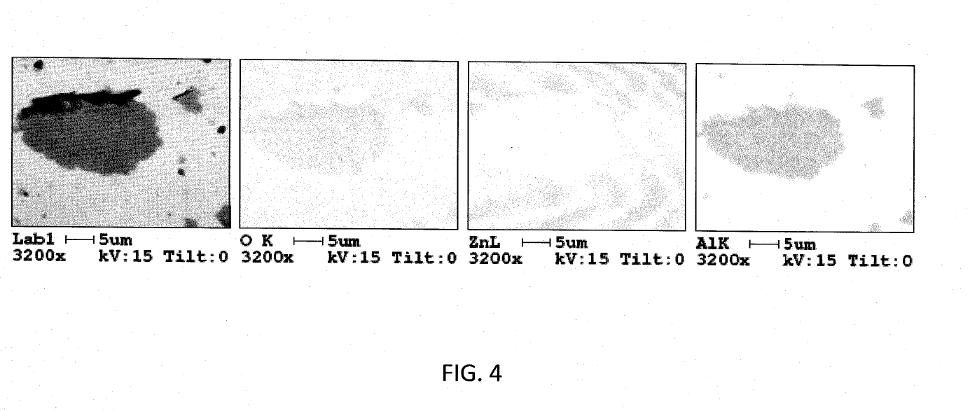

FIG. 2 provides images of energy dispersive X-ray spectroscopy (EDX) mapping of the target material obtained in Example 1, which is an example of a target material according to the invention (from left to right: visual, oxygen, aluminium, zinc). The images of FIG. 2 show a homogeneous distribution and no alumina, or detached zinc aluminate domains. The homogeneous distribution of the microstructure of the target material contributed to the low arc rate measured in Example 1. FIGS. 3 and 4 provide images of energy dispersive X-ray spectroscopy (EDX) mapping of the target materials used in Examples 2 and 3, respectively, which were commercially available target materials. In the images of FIGS. 3 and 4, clear regions of inhomogeneity and clear regions of highly concentrated Al content, with a strong tendency of the domain border to detach from the ZnO matrix, can be seen. The EDX map of Si was added to FIG. 3. The microstructure of the target materials of Examples 2 and 3 contribute to the high arc rates measured in Examples 2 and 3.

The target material of the present invention provides economic and quality improvements over currently available target materials. Targets that are less sensitive to arcing, such as a target produced with the target material of the present invention, can be sputtered with higher power loads, thus enabling considerable increases in deposition rates. As such, targets that are less sensitive to arcing can be used to achieve considerably higher deposition rates. This ability leads to higher production throughput and hence lower costs. In addition, AZO thin films deposited with higher power load generally have better electro-optical properties. Table 2 provides data showing the improved electro-optical properties. Further, an increase of power load for a rotary AZO from 18 kW/m (state-of-the-art) to 27 kW/m for a 1000 nm AZO coating (as used in a CIGS product), leads to an overall reduction in coating cost of approximately 25%. In addition, a lower arc rate improves the coating quality (e.g., less pinholes, less defects), which might allow the usage of thinner coatings for the same sheet resistance.

### Example 4

A rotary cathode on which an AZO-2% target of the present invention was used as a sputtering target and a substrate was passed 8 times under the cathode with two different substrate speeds: 1.3 m/min (25 kW/m) and 1.04 m/min (20 kW/m). Coatings have a thickness of 1200 nm were deposited on clear glass (Schott B270-1 mm thickness) at 200° C. substrate temperature. The sputtering pressure was approximately 5.8E-03 mbar pressure with 0.68% O₂ in the gas flow. Measured properties of the 1200 nm AZO-2% coatings deposited on the substrate are provided in Table 2. It can be seen that the values obtained for sheet resistance, resistivity, mobility and carrier concentration of the coatings are very good.

TABLE 2

| | Sheet | | | |
|---|---|---|---|---|
| | resistance | | | Carrier |
| | (Eddy | Resistivity | Mobility | concentration |
| Power load | Current) | (hall) | (Hall) | (Hall) |
| kW/m | Ohm/sq | μohm.cm | cm²/(V.s) | cm⁻³ |
| 20 | 10.6 | 1262 | 17.8 | 2.8E+20 |
| 25 | 7.0 | 844 | 23.2 | 3.2E+20 |

While specific embodiments and/or details of the invention have been shown and described above to illustrate the application of the principles of the invention, it is understood that this invention may be embodied as more fully described in the claims, or as otherwise known by those skilled in the art (including any and all equivalents), without departing from such principles.

We claim:

1. A ceramic sputtering target material comprising a homogeneous distribution of a ZnAl₂O₄ phase in a hexagonal ZnO phase, said ZnO phase comprising less than 1 wt % of elemental Al in solid solution, expressed versus the total weight of said target material, and wherein less than 1% of the total Al in said target material is present in Al₂O₃ domains in said target material.

2. The target material according to claim 1, comprising between 250 ppm and 2 wt % of total Al.

3. The target material according to claim 1, wherein said ZnO phase comprises less than 1 wt % of elemental Al in solid solution, expressed versus the weight of said ZnO phase.

4. The target material according to claim 1, said target material being substantially free of Al₂O₃ domains larger than 0.5 μm.

5. The target material according to claim 1, wherein said ZnAl₂O₄ phase comprises domains having an average equivalent diameter of less than 2 μm.

6. A process for manufacturing the ceramic sputtering target material of claim 1, comprising:
providing a ZnO powder having an average particle size less than 1 μm and an Al₂O₃ powder having an average particle size less than 1 μm,
dispersing said ZnO and Al₂O₃ powders, a sintering aid and a binder homogeneously in an aqueous slurry,
spray-drying said slurry so as to obtain a dried granulate having an apparent density above 1.1 g/cm³, and a tap density above 1.2 g/cm³,
pressing said dried granulate to form a green body having a density above 50% of the theoretical density of a sputtering target to be made with said ceramic sputtering target material, and
sintering said green body at a temperature between 1200 and 1550° C. to obtain said ceramic sputtering target material.

7. The process according to claim 6, wherein there is provided, in addition to ZnO and Al₂O₃ powders, up to 5 wt % of organic materials used as binder material and dispersant.

8. The process according to claim 6, wherein said Al₂O₃ powder has an average particle size which is smaller than the average particle size of said ZnO powder.

9. The process according to claim 6, wherein said ZnO powder has an average particle size between 150 nm and 1200 nm, and said Al₂O₃ powder has an average particle size between 50 and 800 nm.

10. The process according to claim 6, wherein said ZnO and Al₂O₃ powders each have a purity of at least 99.9%.

11. The process according to claim 6, wherein said dried granulate has a tap density between 1.3 and 1.5 g/cm³.

12. The process according to claim 6, wherein said ZnO and Al₂O₃ powders are partly or totally replaced by compounds comprising both alumina and zinc oxide.

13. A sputtering target manufactured with the ceramic sputtering target material of claim 1, said sputtering target having a density of at least 95% of the theoretical density.

14. The sputtering target of claim 13, wherein the sputtering target is a hollow rotary target having an inner diameter of between 130 and 140 mm and an outer diameter between 155 and 185 mm.

15. An aluminum doped zinc oxide coating manufactured using the sputtering target of claim 13.

16. The aluminum doped zinc oxide coating of claim 15, manufactured in a DC sputtering process with a power of more than 25 kW/m.

17. The process of claim 7, wherein a sintering aid is provided.

18. The process of claim 17, wherein the sintering aid is MgO.

19. The process of claim 12, wherein the compound comprising both alumina and zinc oxide is a zincate phase.
